(19) United States
(12) Patent Application Publication
(10) Pub. No.: US 2020/0103250 A1
(43) Pub. Date: Apr. 2, 2020

(54) SENSOR SYSTEM FOR DETERMINING AT LEAST ONE ROTATIONAL CHARACTERISTIC OF AN ELEMENT ROTATING ABOUT AT LEAST ONE AXIS OF ROTATION

(71) Applicant: Robert Bosch GmbH, Stuttgart (DE)

(72) Inventors: Andre Yashan, Stuttgart (DE); Dayo Oshinubi, Rutesheim (DE); Fabian Utermoehlen, Lippstadt (DE); Stefan Leidich, Rutesheim (DE)

(21) Appl. No.: 16/469,220

(22) PCT Filed: Oct. 23, 2017
(86) PCT No.: PCT/EP2017/076977

§ 371 Date: Jun. 13, 2019

(30) Foreign Application Priority Data
Dec. 13, 2016 (DE) 10 2016 224 856.1

(51) Int. Cl. G01D 5/14; G01D 5/20; G01R 33/09; G01P 3/487

(52) U.S. Cl. CPC G01D 5/145; G01P 3/487; G01R 33/09; G01D 5/2013

(57) ABSTRACT

A sensor system for determining at least one rotational characteristic of an element rotating about at least one axis of rotation; the sensor system including at least one signal-generating wheel connectable to the rotating element. The signal-generating wheel has a signal-generating wheel profile. The sensor system further includes at least one inductive position sensor; the inductive position sensor having at least one coil set-up that includes at least one operating coil and at least one receiving coil. In addition, the sensor system includes at least one phase detector; the phase detector including at least one magnetic field generator and at least one magnetic sensor element.

### BACKGROUND INFORMATION

Numerous conventional sensors measure at least one rotational characteristic of rotating elements. In this context, a rotational characteristic is generally to be understood as a characteristic, which describes the rotation of the rotating element at least partially. In this case, it may be, for example, an angular velocity, a rotational speed, an angular acceleration, an angle of rotation or another characteristic, which may characterize a continuous or discontinuous, uniform or non-uniform rotation of the rotating element. Examples of such sensors are described in Konrad Reif (Ed.): Sensors in the Motor Vehicle, 2nd Edition, 2012, pp. 63-74 and 120-129.

For example, a position of a camshaft of an internal combustion engine relative to a crankshaft may be determined by a so-called phase detector with the aid of a Hall-effect sensor. A signal-generating wheel is typically attached to the rotating shaft. Teeth may be situated on the signal-generating wheel, the teeth being picked up by the Hall-effect sensor when the camshaft rotates. Thus, a method for determining a phase angle of an adjustable camshaft of an internal combustion engine, which includes a signal-generating wheel and a cam phaser, is described in German Patent Application No. DE 10 2012 213 539 A1. The phase angle of the camshaft is determined from phase-edge-triggered interrupts triggered by the signal-generating wheel, as well as from a model, which is a function of at least one operating parameter of the cam phaser.

However, such methods do not allow continuous position measurement. Absolute angular measurement in a measuring range of 360° is not possible. The resolution is also limited by the small diameters of the signal-generating wheels used. These small diameters result in minimal gap sizes, which must be maintained. In addition, absolute position determination is only possible in a dynamic case, when the signal-generating wheel is rotating. Therefore, instantaneous availability of an angular position in response to the switching-on of the voltage supply, a true power-on function, is not given. In particular, a position is not known precisely upon the starting of a motor of the internal combustion engine. In addition, such methods have a high sensitivity to stray magnetic fields.

An inductive linear and rotational position sensor is described in U.S. Pat. No. 7,449,878 B2. A device having an operating coil and a receiving coil is described. The operating coil is excited by an excitation source and generates a magnetic flux. The receiving coil generates a receiving signal, using an inductive coupling between the operating coil and the receiving coil.

In spite of improvements brought about by such sensor devices, there is still room for improvement. Such sensor devices may have a complex construction. Thus, in particular, simple installation and removal of the sensor devices is not possible.

### SUMMARY

In accordance with the present invention, an example sensor system for determining at least one rotational characteristic of a rotating element is provided. In the scope of the present invention, a “sensor system” is understood to be, in principle, any device, which is suitable for measuring the at least one rotational characteristic, and which may generate, for example, at least one electrical measuring signal, such as a voltage or a current, corresponding to the measured characteristic. Combinations of characteristics may also be measurable.

In the scope of the present invention, a “rotational characteristic” is understood to be, in principle, a characteristic, which at least partially describes the rotation of the rotating element. In this case, it may be, for example, an angular velocity, a rotational speed, an angular acceleration, an angular position or another characteristic, which may at least partially characterize a continuous or discontinuous, uniform or non-uniform rotation of the rotating element. For example, the rotational characteristic may be a position, in particular, an angular position, or a rotational speed, or a combination of both variables. Other characteristics and/or other combinations of characteristics may also be measurable. In the scope of the present invention, an “angular position” is understood to be, in principle, a rotational angle of a device capable of rotating, for example, of the rotating element or of the signal-generating wheel, with respect to an axis standing vertically on the axis of rotation.

The sensor system may be configured, in particular, for use in a motor vehicle. In the scope of the present invention, a “rotating element” is understood to be, in principle, any element, which has an axis of rotation and rotates about it. For example, the rotating element may be a shaft in a driving machine, for example, a camshaft. For example, an angular position of a camshaft or a rotational speed of a camshaft or a combination of the two variables may be determined.

The example sensor system for determining at least one rotational characteristic of an element rotating about at least one axis of rotation has at least one signal-generating wheel connectable to the rotating element. The signal-generating wheel has a signal-generating wheel profile. The sensor system includes at least one inductive position sensor. The inductive position sensor includes at least one coil set-up, which contains at least one operating coil and at least one receiving coil. The sensor system further includes at least one phase detector. The phase detector includes at least one magnetic field generator and at least one magnetic sensor element.

In the scope of the present invention, a “signal-generating wheel” is understood to be, in principle, any component, which is connectable to the rotating element and, when connected to the rotating element, is configured to produce at least one measurable signal, in particular, a change in magnetic field, per revolution of the rotating element. In the scope of the present invention, a “signal-generating wheel profile” is understood to be, in principle, all of the profile elements and spaces of the signal-generating wheel that are situated between the profile elements. In the scope of the present invention, a “profile element” of the signal-generating wheel is understood to be, in principle, any protuberance of the contour of the signal-generating wheel, in particular, a salient, such as a pin-shaped, tooth-shaped or serrated salient, or a notch or cut-out, such as a hole.

In the scope of the present invention, an “inductive position sensor” is understood to be, in principle, any sensor, which can generate a measuring signal, in particular, an electric measuring signal, for example, a voltage or current, corresponding to a measured characteristic; generation of the measuring signal being based upon a change in a magnetic flux. In particular, the measured characteristic may include a position, for example, an angular position. In particular, the inductive position sensor may be an inductive magnetic sensor. However, in principle, other embodiments are also possible.

In the scope of the present invention, a “coil set-up” is understood to be, in principle, any device, which includes at least one coil. In the scope of the present invention, a “coil” is understood to be, in principle, any component, which has an inductance and is suitable for generating a magnetic field in response to the flow of current. In the scope of the present invention, an “operating coil” is understood to be, in principle, a coil, which generates a magnetic flux in response to the application of an electrical voltage and/or an electrical current. In the scope of the present invention, a “receiving coil” is understood to be, in principle, a coil, which, on the basis of an inductive coupling between the operating coil and the receiving coil, is configured to generate a signal that is a function of the inductive coupling.

In the scope of the present invention, a “phase detector” is understood to be, in principle, any sensor, which is suitable for determining, at least once per revolution, the rotational speed and/or the angular position of a rotating element connected to a signal transmitter. In the scope of the present invention, a “signal transmitter” is understood to be, in principle, any device, which is situated on the rotating element or connected or connectable to the rotating element and is suitable for producing at least one measurable signal, for example, a change in magnetic field, per revolution of the rotating element. For example, the signal-generating wheel, in particular, the at least one profile element of the signal generating wheel, which has already been described above and is explained in even more detail in the following, may act as a signal transmitter. Other embodiments are also possible. Thus, the rotating element may also include, for example, an optical or capacitive signal transmitter.

In the scope of the present invention, a “magnetic field generator” is basically understood to be any device, which is configured to generate a magnetic field, in particular, a magnetic field constant over time. The generation may be continuous or also time-limited. In particular, the magnetic field generator may include a permanent magnet and/or an electromagnet, for example, a current-carrying coil, in particular, a current-carrying coil having an iron core. In the scope of the present invention, a “magnetic sensor element” is basically understood to be any device, which is configured to measure at least one characteristic of a magnetic field, and which may generate, for example, at least one electrical measuring signal, such as a voltage or a current, corresponding to the measured characteristic. Combinations of characteristics may also be measurable. In particular, the measured characteristic may be a magnetic field intensity. In particular, the magnetic sensor element may include at least one element selected from the group made up of: a Hall-effect element and a magnetoresistive element.

The coil set-up may be situated on at least one circuit substrate. The circuit substrate may be positioned substantially coaxially to the axis of rotation. The circuit substrate may surround the signal-generating wheel or a circular segment of the signal-generating wheel substantially circularly or in the form of a circular segment. In the scope of the present invention, the term “substantially circularly” is basically understood to mean that the component described has a radius of curvature. Within the component, the radius of curvature may vary by a value of 0% to 80%, preferably, 0% to 50%, more preferably, 0% to 20%, and particularly preferably, 0% to 5%. In particular, the radius of curvature may also be constant. Alternatively or additionally, the circuit substrate may also be made up of two or more segments, which may each be, for example, plane or also curved, and which may be, for example, connected to each other. On the whole, the segments may also be positioned coaxially to the axis of rotation, even if the individual segments are then positioned, for example, tangentially.

The sensor system may be configured to measure the inductive coupling and/or a change in the inductive coupling between the operating coil and the receiving coil. In addition, the sensor system may be configured to acquire an electrical measuring signal of the phase detector. The electrical measuring signal may be, in particular, a voltage signal. The electrical measuring signal of the phase detector may be, in particular, an electrical measuring signal of the magnetic sensor element, in particular, of the Hall-effect element. In particular, the sensor system may be configured to measure the inductive coupling and/or the change in the inductive coupling between the operating coil and the receiving coil produced by a movement and/or a position of the signal-generating wheel. In addition, the sensor system may be configured to acquire the electrical measuring signal of the phase detector produced by the position of the signal-generating wheel. Furthermore, the sensor system may be configured to determine an angular position of the rotating element from the inductive coupling and/or change in the inductive coupling between the operating coil and the receiving coil produced by the movement and/or the position of the signal-generating wheel. Moreover, the sensor system may be configured to determine the angular position and/or the rotational speed of the rotating element with the aid of at least one electrical measuring signal of the phase detector produced by the position of the signal-generating wheel. In particular, the sensor system may be configured to determine the angular position and/or the rotational speed of the rotating element, using at least two electrical measuring signals of the phase detector produced by the position of the signal-generating wheel. In particular, the sensor system may be configured to allow the angular position of the rotating element to be available upon the switching-on of a voltage supply. The above-described characteristic of availability upon the switching-on of the voltage supply is also referred to as a true power-on function. The sensor system may have, in particular, a true power-on function. In particular, the sensor system may be configured to transmit the electrical signal of the magnetic sensor element to a control unit. In addition, the sensor system may include an evaluation unit. The evaluation unit may include at least one evaluation circuit. The evaluation unit may be situated with the coil set-up on a common circuit substrate. The evaluation unit may also be positioned separately from the coil set-up on a further circuit substrate.

The operating coil may include at least one excitation winding. The receiving coil may include at least one receiving winding. A receiving winding may include at least two partial windings. The partial windings may be oriented countercurrently. In particular, the receiving coil may be made up of one receiving winding, the receiving winding being made up of two partial windings, the partial windings being oriented countercurrently. The sensor system may include a plurality of receiving coils, for example, a receiving coil system, in particular, a sine/cosine system or a multiphase system. In principle, other coil systems are also possible. The sensor system may be configured to model a sine system, a cosine system or a multiphase system for detection. In particular, the sensor system may have a quantity of 1 to 100 receiving coils, preferably, 2 to 10 receiving coils, particularly preferably, 3 receiving coils. In particular, the receiving coils may each be made up of at least two partial windings, the partial windings directly following each other being able to be oriented countercurrently. In particular, the receiving coils may exhibit an electrical phase shift with respect to each other. In particular, the partial windings of the different receiving coils may be positioned so as to be staggered in accordance with the electrical phase shift.

In particular, the magnetic field generator may include at least one element selected from the group made up of a permanent magnet and an electromagnet. The signal-generating wheel includes at least one profile element. The profile element may be selected from the group made up of: a salient, in particular, a pin-shaped, a tooth-shaped or a serrated salient, for example, a tooth; a notch; a cut-out, for example, a hole; a track contoured in the width of the signal-generating wheel. In this connection, a width of the signal-generating wheel may be understood to be a height of a cylinder sleeve of the signal-generating wheel. In particular, the signal-generating wheel may include a plurality of profile elements. In particular, the plurality of profile elements may be positioned so as to be distributed over the circumference of the signal-generating wheel. For example, the profile elements may be positioned equidistantly and/or periodically. Other embodiments of the signal-generating wheel profile are also possible. Thus, the profile elements may be positioned so as to not be equidistant and/or not be periodic. The signal-generating wheel may include at least one material selected from the group made up of: an electrically conductive material; a ferromagnetic material; a metal. In particular, the profile element may include at least one material selected from the group made up of: an electrically conductive material; a ferromagnetic material; a metal. In particular, the sensor system may include at least two signal-generating wheels. In particular, the signal-generating wheels may have different signal-generating wheel profiles.

The circuit substrate may surround the signal-generating wheel and/or a circular segment of the signal-generating wheel substantially circularly. In particular, at at least one angular position of the signal-generating wheel, the coil set-up, in particular, the coil set-up situated on the circuit substrate, may cover at least one profile element and at least one space between two profile elements of the signal-generating wheel. The circuit substrate may be designed to be flexible. In particular, the circuit substrate may include a flexible material. The circuit substrate may be selected from the group made up of: a circuit board, in particular, a rigid-flex circuit board, for example, a curved rigid-flex circuit board; a rigid circuit board, in particular, a rigid circuit board having notches; a circuit card; a board and a printed circuit, in particular, a printed circuit board (PCB). In particular, the circuit substrate may have at least two plane surfaces. The plane surfaces may be positioned at an angle to each other. In particular, the circuit substrate may include at least one connecting element; the connecting element interconnecting the plane surfaces. In particular, the plane surfaces may form an angle; the angle being able to have a value of 10° to 180°, preferably, 30° to 150°, and particularly preferably, 60° to 120°. In addition, the circuit substrate may be situated in a housing, in particular, in an injection-molded housing.

The rotating element has at least one axis of rotation. The at least one signal-generating wheel is connectable to the rotating element. The signal-generating wheel may also have an axis of rotation. In particular, the rotating element and the signal-generating wheel may have a common axis of rotation. The signal-generating wheel may be positioned concentrically about the rotating element. A basic form of the signal-generating wheel may be cylindrical. The axis of rotation may be an axis of symmetry parallel to a height of the cylinder. The signal-generating wheel may be connected to the rotating element. The signal-generating wheel may be mounted on the rotating element, using, for example, at least one fastening element. The signal-generating wheel may be fixed concentrically on the rotating element. In response to a rotary movement of the rotating element, the signal-generating wheel may rotate together with the rotating element. A position, in particular, an angular position of the signal-generating wheel, may correspond to a position, in particular an angular position of the rotating element.

In a further aspect of the present invention, an example method for determining a rotational characteristic of an element rotating about at least one axis of rotation is provided. The method includes using at least one signal-generating wheel connectable to the rotating element; the signal-generating wheel having a signal-generating wheel profile. The method includes the following steps, preferably in the order indicated. A different order is also theoretically possible. In addition, one or more or all of the method steps may also be repeated. Furthermore, two or more of the method steps may also be carried out so as to overlap completely or partially in time, or they may be executed simultaneously. In addition to the method steps mentioned, the method may also include further method steps.

The method steps include:
a) picking up at least one inductive signal with the aid of at least one inductive position sensor; the inductive position sensor including at least one coil set-up, which contains at least one operating coil and at least one receiving coil; and
b) picking up at least one phase detector signal with the aid of at least one phase detector; the phase detector including at least one magnetic field generator and at least one magnetic sensor element.

The method may be executed, in particular, using a sensor system according to the present invention, that is, according to one of the above-mentioned specific embodiments, or according to one of the specific embodiments described below in even more detail. Accordingly, for definitions and optional refinements, reference is made extensively to the description of the sensor element. However, in principle, other refinements are also possible.

In particular, the inductive signal may include at least one signal selected from the group made up of an inductive coupling in the coil set-up and a change in an inductive coupling in the coil set-up. In addition, the phase detector signal may include at least one voltage signal of the magnetic sensor element. In particular, the inductive coupling and/or the change in the inductive coupling in the coil set-up may be a function of a movement and/or a position of the signal-generating wheel. In particular, the phase detector signal may be a function of a position of the signal-generating wheel. In addition, the method may include determining the angular position of the rotating element with the aid of the measured inductive coupling and/or change in the inductive coupling in the coil set-up dependent on the position and/or the movement of the signal-generating wheel. Furthermore, the method may include determining the angular position and/or the rotational speed of the rotating element with the aid of at least one phase detector signal produced by the position of the signal-generating wheel. Moreover, the method may include processing the at least one acquired phase detector signal, using an evaluation circuit. The method may also include transmitting the at least one acquired phase detector signal to a control unit.

The example device and the example method in accordance with the present invention may have numerous advantages over conventional devices and methods. In particular, in the scope of the present invention, an inductive position sensor, in particular, an absolute angular position sensor, may be combined with a phase detector. It is possible for the set-up of the inductive position sensor and of the phase detector according to the present invention to provide a marked advantage in installation and removal in comparison with the related art, in particular, when using the sensor system for detecting the position of a camshaft. Thus, in particular, it is possible that no additional space is needed. In addition, in contrast to the related art, it is possible for the sensor system, for example, the sensor set-up, not to have to surround the entire region of the rotating element, for example, of the rotating shaft, but for it to be able to face it only radially in a circular segment. It is possible for a sensor system of the present invention to be inexpensive. Furthermore, it is possible for a measuring range of a sensor system of the present invention to be expanded to 360°, for example, with the aid of the Nonius principle (Vernier method), by evaluation with two or more signal-generating wheels and/or different signal-generating wheel profiles, in particular, of different numbers of teeth, for measuring an angular position, in particular, for measuring an absolute angular position, of a signal-generating wheel and/or of a rotating element, in particular, a shaft position. In particular, at at least one angular position of the signal-generating wheel, the coil set-up, in particular, the coil set-up situated on the circuit substrate, may cover at least one profile element and at least one space between two profile elements of the signal-generating wheel. In particular, an opening angle α of the coil set-up may correspond to at least one opening angle β, of a circular segment of the signal-generating wheel, including at least one profile element and at least one space between two profile elements. Through this, it is possible for a maximum angular resolution to be reproduced.

It is possible for a sensor system of the present invention to supply both an angular position of the rotating element, in particular, an absolute angular position, and, with the aid of the phase detector, real-time-capable trigger signals, for example, for the engine control unit. It is possible that this may not be ensured by the use of only an inductive position sensor, in particular, an inductive angular position sensor, due to the analog and digital signal processing with the corresponding processing time.

In addition, using the combination of the inductive position sensor and the phase detector, it is possible for a sensor system of the present invention to be able to provide a greater accuracy in comparison with the related art. Furthermore, with the aid of a sensor system according to the present invention, it may be possible for requirements of functional reliability, in particular, with regard to availability, as well, to be easier to fulfil, since, in particular, in the event of the failure of the inductive position sensor or of the phase detector, in each instance, the other sensor, that is, in particular, the phase detector or the inductive position sensor, may provide signals to the engine control unit, in particular, at a lower accuracy. This may correspond, for example, to operation under emergency conditions without a higher loss of performance. In addition, it is possible for lag errors of the inductive position sensor, in particular, of the absolute angular position sensor, to be able to be compensated for at higher rotational speeds. Furthermore, it is possible for measuring errors of the phase detector, in particular, of the magnetic field sensor, due to stray magnetic fields from the inductive position sensor, in particular, from the inductive angular position sensor, to be able to be corrected during operation, since this may have a high degree of robustness with regard to magnetic fields. Moreover, it is possible for a sensor system of the present invention to allow the angular position, in particular, the absolute angular position, of the rotating element to be made available upon the switching-on of a voltage supply. In particular, it is possible for a sensor system of the present invention to possess a true power-on function. A true power-on function is increasingly being required by the original equipment manufacturer (OEM).

### BRIEF DESCRIPTION OF THE DRAWINGS

Further optional details and features of the present invention are derived from the description below of preferred exemplary embodiments, which are represented schematically in the figures.

FIG. 1 shows a top view of a schematic representation of an exemplary embodiment of a sensor system according to the present invention.

FIGS. 2 and 3 show in each instance, a schematic representation of an exemplary embodiment of a coil set-up.

FIG. 4 shows a schematic view of an exemplary embodiment of a circuit substrate.

FIGS. 5A, 5B and 6 show schematic views of exemplary embodiments of a signal-generating wheel having a signal-generating wheel profile, as well as of a further signal-generating wheel profile (FIG. 6).

### DETAILED DESCRIPTION OF EXAMPLE EMBODIMENTS

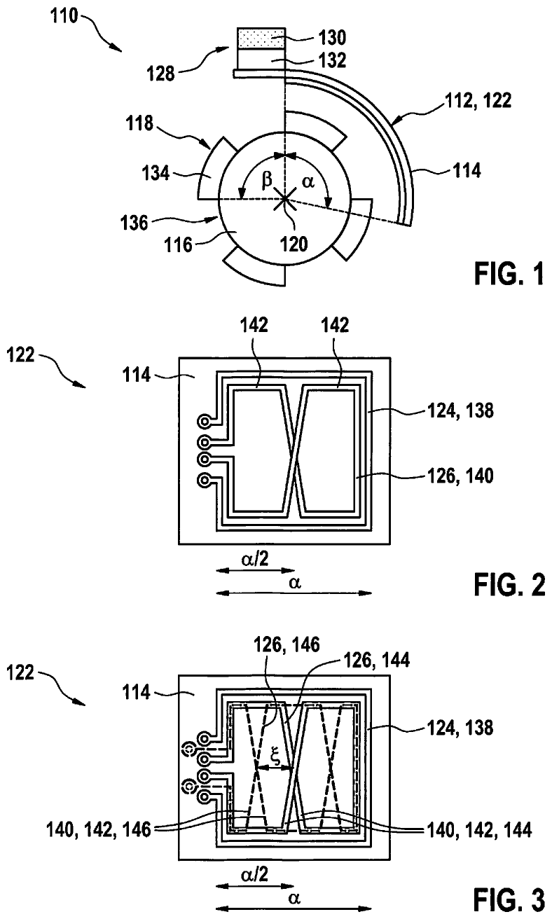

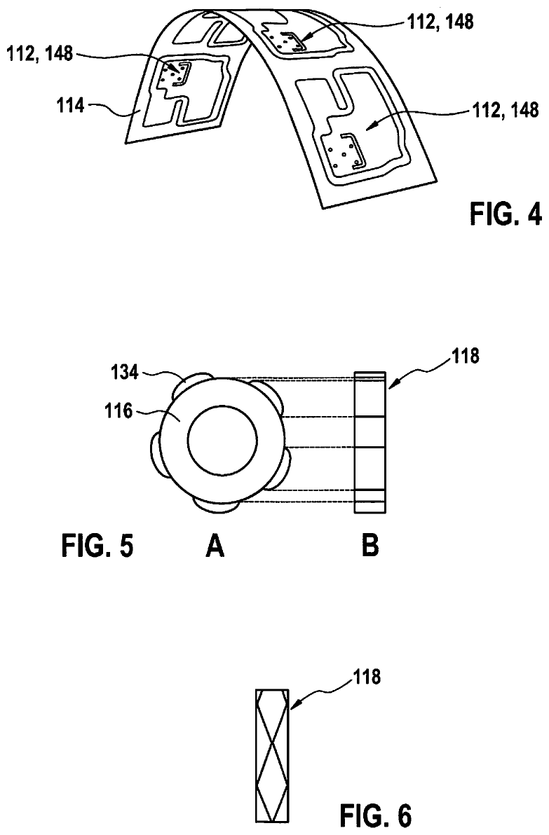

FIG. 1 shows a top view of a schematic representation of an exemplary embodiment of a sensor system 110 according to the present invention. FIGS. 2 and 3 each show a schematic representation of an exemplary embodiment of a coil set-up 112 for use in sensor system 110 according to FIG. 1. FIG. 4 shows a schematic view of an exemplary embodiment of a circuit substrate 114, which may also be used in sensor system 110 according to FIG. 1. FIGS. 5A, 5B and 6 show schematic exemplary embodiments of a signal-generating wheel 116 having a signal-generating wheel profile 118, which may also be used in sensor system 110 according to FIG. 1. In the following, these figures are explained together.

Sensor system 110 may be configured, in particular, for use in a motor vehicle. In particular, sensor system 110 may be configured to measure at least one rotational characteristic of a camshaft. For example, sensor system 110 may be configured to measure an angular position of the camshaft and/or a rotational speed of the camshaft. In particular, sensor system 110 may include one or more additional functional elements not shown in the figures, such as electrodes, electrode leads and contacts, a plurality of layers, heating elements or other elements, as shown, for example, in the related art mentioned above.

Sensor system 110 for determining at least one rotational characteristic of an element rotating about at least one axis of rotation 120 has at least one signal-generating wheel 116 connectable to the rotating element. Signal-generating wheel 116 has a signal-generating wheel profile 118. Sensor system 110 includes at least one inductive position sensor 122. Inductive position sensor 122 includes at least one coil set-up 112, which contains at least one operating coil 124 and at least one receiving coil 126. Sensor system 110 further includes at least one phase detector 128. Phase detector 128 includes at least one magnetic field generator 130 and at least one magnetic sensor element 132.

FIG. 1 shows, inter alia, the phase detector 128 having magnetic field generator 130 and magnetic sensor element 132. Magnetic field generator 130 may include at least one element selected from the group made up of: a permanent magnet; an electromagnet, for example, a current-carrying coil, in particular, a current-carrying coil having an iron core.

Magnetic sensor element 132 may include at least one element selected from the group made up of: a Hall-effect element and a magnetoresistive element. Coil set-up 112 may be situated on at least one circuit substrate 114, as can be seen in FIGS. 2 and 3. Circuit substrate 114 may be positioned substantially coaxially to axis of rotation 120, as shown in FIG. 1. Circuit substrate 114 may surround signal-generating wheel 116 or a circular segment of signal-generating wheel 116 in a substantially circular manner, as can be seen in FIG. 1, as well. In particular, at at least one angular position of signal-generating wheel 116, coil set-up 112, in particular, the coil set-up 112 situated on circuit substrate 114, may cover at least one profile element 134 and at least one space 136 between two profile elements 134 of signal-generating wheel 116. In particular, an opening angle α of coil set-up 112, shown in FIGS. 1, 2 and 3, may correspond to at least one opening angle β of the circular segment of signal-generating wheel 116, likewise shown in FIG. 1, the opening angle β including at least one profile element 134 and at least one space 136 between two profile elements 134. Through this, it is possible for a maximum angular resolution to be reproduced.

Circuit substrate 114 may be designed to be flexible. For example, the circuit substrate may be designed to be flexible and/or curved, in particular, in the shape of a circle or circular segment, as shown in FIG. 4. In particular, circuit substrate 114 may include a flexible material. Circuit substrate 114 may be selected from the group made up of: a circuit board, in particular, a rigid-flex circuit board, for example, a curved rigid-flex circuit board; a rigid circuit board, in particular, a rigid circuit board having notches; a circuit card; a board and a printed circuit, in particular, a printed circuit board (PCB). In addition, circuit substrate 114 may be situated in a housing not shown here, in particular, in an injection-molded housing.

FIGS. 2 and 3 show, inter alia, two different coil set-ups 112 by way of example. Operating coil 124 may include at least one excitation winding 138. Receiving coil 126 may include at least one receiving winding 140. Receiving winding 140 may include at least two partial windings 142. Partial windings 142 may be oriented countercurrently. In particular, receiving coil 126 may be made up of a receiving winding 140; receiving winding 140 being made up of two partial windings 142; the partial windings 142 being oriented countercurrently. Sensor system 110 may include a plurality of receiving coils 126, for example, a receiving coil system, in particular, a sine/cosine system or a multiphase system. In principle, other coil systems are also conceivable. Sensor system 110 may be configured to model a sine system, a cosine system or a multiphase system for detection. In particular, sensor system 110 may have a quantity of 1 to 100 receiving coils 126, preferably, 2 to 10 receiving coils 126, particularly preferably, 3 receiving coils 126. In particular, receiving coils 126 may each be made up of at least two partial windings 142; in each instance, the partial windings 142 immediately following each other being able to be oriented countercurrently. In particular, receiving coils 126 may exhibit an electrical phase shift with respect to each other. In particular, in each instance, the at least one receiving winding 140 of receiving coils 126, in particular, the partial windings 142 oriented countercurrently, may be staggered according to the electrical phase shift, as shown illustratively in FIG. 3 for a two-phase system that includes a first receiving coil 144 and a second receiving coil 146. In the case of two receiving coils 126, a shift in particular, a geometric twist, of second receiving coil 146 in comparison with first receiving coil 144, in particular, of partial windings 140 of second receiving coil 146 in comparison with partial windings 140 of first receiving coil 144, may be derived from:

ξ=α/4 (1)

In a multiphase system including a quantity m of at least 3 receiving coils, the shift ξ may be derived from:

ξ=α/m (2)

In another preferred exemplary embodiment, sensor system 110 may include an operating coil 124 and three receiving coils 126. Receiving coils 126 may each be made up of at least two partial windings 142; the partial windings directly following each other being oriented countercurrently. Receiving coils 126 may exhibit an electrical phase shift of 120° with respect to each other. In particular, partial windings 142 of the three receiving coils 126 may be positioned so as to be staggered in accordance with the electrical phase shift.

FIGS. 5A and 5B show a top view (FIG. 5A) and a side view (FIG. 5B) of an example of a signal-generating wheel 116 having a signal-generating wheel profile 118. FIG. 6 shows a side view of an alternative embodiment of a signal-generating wheel profile 118. Signal-generating wheel 116 includes at least one profile element 134. While the profile elements 134 in the embodiment of FIG. 5B extend across an entire width of signal-generating wheel 116, the profile elements 134 in the alternative embodiment of FIG. 6 are contoured over the width and form a track profiled in the width. For example, as is apparent in FIG. 6, profile elements 134 each have a rhombic shape. However, other shapes are also conceivable. The at least one profile element 134 may be selected, in particular, from the group made up of: a salient, in particular, a pin-shaped, a tooth-shaped or a serrated salient, for example, a tooth; a notch; a cut-out, for example, a hole; a track profiled in the width of the signal-generating wheel. Signal-generating wheel 116 may include at least one material selected from the group made up of: an electrically conductive material; a ferromagnetic material; a metal. In particular, profile element 134 may include at least one material selected from the group made up of: an electrically conductive material; a ferromagnetic material; a metal. In particular, sensor system 110 may include at least two signal-generating wheels 116. In particular, signal-generating wheels 116 may include different signal-generating wheel profiles 118.

Sensor system 110 may be configured to measure the inductive coupling and/or a change in the inductive coupling between operating coil 124 and receiving coil 126. In addition, sensor system 110 may be configured to acquire an electrical measuring signal of phase detector 128. The electrical measuring signal may be, in particular, a voltage signal. The electrical measuring signal of phase detector 128 may be, in particular, an electrical measuring signal of magnetic sensor element 132, in particular, of the Hall-effect element. In particular, sensor system 110 may be configured to measure the inductive coupling and/or the change in the inductive coupling between operating coil 124 and receiving coil 126 produced by a movement and/or a position of signal-generating wheel 116. In addition, sensor system 110 may be configured to acquire the electrical measuring signal of phase detector 128 produced by the position of the signal-generating wheel. Furthermore, sensor system 110 may be configured to determine an angular position of the rotating element from the inductive coupling and/or change in the inductive coupling between operating coil 124 and receiving coil 126 produced by the movement and/or the position of signal-generating wheel 116. Moreover, sensor system 110 may be configured to determine the angular position and/or the rotational speed of the rotating element with the aid of at least one electrical measuring signal of phase detector 128 produced by the position of signal-generating wheel 116. In particular, sensor system 110 may be configured to determine the angular position and/or the rotational speed of the rotating element, using at least two electrical measuring signals of phase detector 128 produced by the position of signal-generating wheel 116.

In particular, sensor system 110 may be configured to transmit the electrical measuring signal of phase detector 128 to a control unit not shown here. In addition, sensor system 110 may include an evaluation unit 148. The evaluation unit may include at least one evaluation circuit. The evaluation unit may be positioned with coil set-up 112 on a common circuit substrate 114, as shown in FIG. 4. The evaluation unit may also be positioned separately from coil set-up 112 on another circuit substrate 114.

The rotating element has at least one axis of rotation 120. The at least one signal-generating wheel 116 is connectable to the rotating element. Signal-generating wheel 116 may also have an axis of rotation 120. In particular, the rotating element and signal-generating wheel 116 may have a common axis of rotation 120. The rotating element and signal-generating wheel 116 may rotate about common axis of rotation 120. As shown in FIG. 1, during rotation, signal-generating wheel 116 may sweep over coil set-up 112 of inductive position sensor 122; the coil set-up of the inductive position sensor being mounted, for example, concentrically about signal-generating wheel 116 and/or about the circular segment of signal-generating wheel 116. An excitation voltage may be applied to operating coil 124. For example, a voltage of 0.5 to 10 V, preferably, a voltage of 1.5 V, at a frequency of 1 MHz to 10 MHz, particular preferably, 5 MHz, may be applied to operating coil 124. The at least one receiving coil 126 may include at least two partial windings 142 oriented countercurrently. When a voltage is applied to operating coil 124, the voltage induced in receiving coil 126 may also be zero, for example, in the absence of signal-generating wheel 116. While sweeping over coil set-up 112, signal-generating wheel profile 118 may change the inductive coupling between operating coil 124 and receiving coil 126. According to the method of the present invention, in this exemplary embodiment, at least one inductive signal, for example, a voltage signal, is picked up by inductive position sensor 122 in accordance with the inductive coupling and/or the change in the inductive coupling, which may be produced by the position of signal-generating wheel 116 and/or the movement of signal-generating wheel 116. In addition, the method may include determining the angular position of signal-generating wheel 116. The angular position of signal-generating wheel 116 may correspond to an angular position of the rotating element. In particular, sensor system 110 may be configured to allow the angular position of the rotating element to be available upon the switching-on of a voltage supply (true power-on function). Furthermore, during rotation, signal-generating wheel 116 may sweep over magnetic sensor element 132 of phase detector 128. Signal-generating wheel profile 118 may influence the magnetic field generated by magnetic field generator 130. According to the method of the present invention, in this exemplary embodiment, the phase detector signal, in particular, the voltage signal of magnetic sensor element 132, is additionally picked up in accordance with the magnetic field produced by the position of signal-generating wheel 116. Furthermore, the method may include determining the angular position of the signal-generating wheel and/or determining the rotational speed of the rotating element with the aid of the at least one phase detector signal. Moreover, the method may include processing the at least one acquired phase detector signal, using an evaluation circuit not shown here. In addition, the method may include transmitting the at least one acquired phase detector signal to a control unit also not shown in the figures.

1-14. (canceled)

15. A sensor system for determining at least one rotational characteristic of an element rotating about at least one axis of rotation, the sensor system comprising:
at least one signal-generating wheel connectable to the rotating element, the signal-generating wheel having a signal-generating wheel profile;
at least one inductive position sensor, the inductive position sensor having at least one coil set-up that includes at least one operating coil and at least one receiving coil;
at least one phase detector, the phase detector including at least one magnetic field generator and at least one magnetic sensor element.

16. The sensor system as recited in claim 15, wherein the magnetic sensor element includes at least one element selected from the group made up of a Hall-effect element and a magnetoresistive element.

17. The sensor system as recited in claim 15, wherein the coil set-up is situated on at least one circuit substrate, the circuit substrate is positioned substantially coaxially to the axis of rotation, and the circuit substrate surrounds the signal-generating wheel or a circular segment of the signal-generating wheel in a substantially circular manner.

18. The sensor system as recited in claim 17, wherein the circuit substrate surrounds the signal-generating wheel or a circular segment of the signal-generating wheel in a substantially circular manner, and at at least one angular position, the coil set-up covers at least one profile element and at least one space between two profile elements of the signal-generating wheel.

19. The sensor system as recited in claim 15, wherein the sensor system is configured to measure an inductive coupling and/or a change in an inductive coupling between the operating coil and the receiving coil, and the sensor system is further configured to acquire an electrical measuring signal of the phase detector.

20. The sensor system as recited in claim 15, wherein the sensor system is configured to measure the inductive coupling and/or change in an inductive coupling between the operating coil and the receiving coil produced by a movement and/or a position of the signal-generating wheel, and wherein the sensor system is further configured to acquire an electrical measuring signal of the phase detector produced by the position of the signal-generating wheel.

21. The sensor system as recited in claim 15, wherein the sensor system is configured to determine an angular position of the rotating element from the inductive coupling and/or a change in an inductive coupling between the operating coil and the receiving coil produced by movement of the signal-generating wheel and/or by a position of the signal-generating wheel, and wherein the sensor system is further configured to determine the angular position and/or a rotational speed of the rotating element with the aid of at least one electrical measuring signal of the phase detector produced by the position of the signal-generating wheel.

22. The sensor system as recited in claim 15, wherein the sensor system is configured to allow an angular position of the rotating element to be available upon a switching-on of a voltage supply.

23. The sensor system as recited in claim 15, wherein the at least one receiving coil is made up of at least two consecutive partial windings, and the consecutive partial windings are oriented countercurrently.

24. The sensor system as recited in claim 15, wherein the signal-generating wheel includes at least one profile element.

25. The sensor system as recited in claim 15, wherein the sensor system includes at least two signal-generating wheels.

26. The sensor element as recited in claim 25, wherein the two signal-generating wheels have different signal-generating wheel profiles.

27. A method for determining at least one rotational characteristic of an element rotating about at least one axis of rotation, the method comprising:
using at least one signal-generating wheel connectable to the rotating element, the signal-generating wheel having a signal-generating wheel profile;
picking up at least one inductive signal with the aid of at least one inductive position sensor, the inductive position sensor having at least one coil set-up that includes at least one operating coil and at least one receiving coil; and
picking up at least one phase detector signal with the aid of at least one phase detector, the phase detector including at least one magnetic field generator and at least one magnetic sensor element.

28. The method as recited in claim 27, further comprising:
determining an angular position of the rotating element with the aid of the measured inductive coupling and/or a change in an inductive coupling in the coil set-up dependent on a position of the signal-generating wheel and/or a movement of the signal-generating wheel; and
determining the angular position and/or a rotational speed of the rotating element with the aid of at least one phase detector signal produced by the position of the signal-generating wheel.
